(19) United States
(12) Patent Application Publication
(10) Pub. No.: US 2026/0208496 A1
(43) Pub. Date: Jul. 23, 2026

(54) SYSTEM AND METHOD FOR MONITORING NORMAL EJECTION OF INKJET INK DROPLETS USING IMAGE REGISTRATION ACCURACY

(71) Applicant: PUKYONG NATIONAL UNIVERSITY INDUSTRY-UNIVERSITY COOPERATION FOUNDATION, Busan (KR)

(72) Inventor: Dong Youn SHIN, Busan (KR)

(73) Assignee: PUKYONG NATIONAL UNIVERSITY INDUSTRY-UNIVERSITY COOPERATION FOUNDATION, Busan (KR)

(21) Appl. No.: 19/539,999

(22) Filed: Feb. 13, 2026

Related U.S. Application Data
(63) Continuation of application No. PCT/KR2025/019077, filed on Nov. 18, 2025.

(30) Foreign Application Priority Data
Nov. 26, 2024 (KR) 10-2024-0171082

(51) Int. Cl. B41J 2/21; B41J 29/393

(52) U.S. Cl. CPC B41J 2/2142; B41J 2/2139; B41J 29/393; B41J 2029/3935

(57) ABSTRACT

An ink droplet image of an inkjet print head that is normally ejecting ink droplets is acquired by a wide-width one-dimensional (1D) line scan camera or a two-dimensional (2D) area scan camera and stored as reference ink droplet image data. An ink droplet ejection image of an inkjet print head to be inspected is acquired by a 1D line scan camera or a 2D area scan camera of an inspection system, and a registration accuracy between the reference ink droplet image data and the ink droplet ejection image to be inspected is calculated. When the registration accuracy is less than a preset registration threshold, the corresponding inkjet print head nozzle is determined to be abnormal, whereas when the registration accuracy is equal to or greater than the preset registration threshold, the corresponding inkjet print head nozzle is determined to be normal.

### CROSS-REFERENCE TO RELATED APPLICATIONS

This is a continuation of International Application No. PCT/KR2025/019077 filed on November 18, 2025, which claims priority to Korean Patent Application No. 10-2024-0171082 filed on November 26, 2024, the entire contents of which are herein incorporated by reference.

### TECHNICAL FIELD

1 The present disclosure relates to a system and method for monitoring normal ejection of inkjet droplets using image registration accuracy. More particularly, the present disclosure relates to a system and method for monitoring whether ink droplets are normally ejected by acquiring an image of ink droplets ejected from an inkjet print head that is normally ejecting ink using a wide-field one-dimensional (1D) line-scan camera or a two-dimensional (2D) area-scan camera, storing the acquired image as reference ink droplet image data, acquiring an ink droplet ejection image of an inkjet print head to be inspected using a 1D line-scan camera or a 2D area-scan camera of an inspection system, calculating a registration accuracy between the reference ink droplet image data and the acquired ink droplet ejection image data, determining a corresponding nozzle of the inkjet print head to be an abnormal nozzle when the registration accuracy is less than a preset registration threshold, and determining the corresponding nozzle to be a normal nozzle when the registration accuracy is equal to or greater than the preset registration threshold.

### Background Art

2 Conventionally, a typical method for forming subpixels of a display panel includes uniformly applying a color resist of one color selected from red, green, and blue over an upper portion of the display panel and then using a photolithography process to leave the color resist of the desired color only on selected subpixels. By repeating this process, a color filter of the display panel is manufactured.

3 However, when manufactured using such a method, material waste is significant, and there is a problem in that photolithography processes are difficult to apply to high-cost materials such as OLED (Organic Light-Emitting Diode) and QD (Quantum Dot), which are vulnerable to subsequent processes involving chemicals and high temperatures. Accordingly, patterning technologies capable of applying a desired amount of ink to a desired area, such as inkjet technology, have attracted attention in the display industry.

4 In manufacturing a display panel, there has been a need to promptly inspect whether ink droplets ejected from an inkjet print head are defective or abnormal. Conventionally, laser phase Doppler measurement methods or vision inspection techniques have been used to monitor the shape, volume, velocity, and ejection angle from the nozzle of the ink droplets.

5 However, the laser phase Doppler measurement method is unable to measure the shape of ink droplets. In particular, when the ink droplets contain particles capable of scattering laser light, there is a problem in that scattering noise makes it impossible to measure the volume, velocity, ejection angle, and other characteristics of the ink droplets.

6 In addition, in a method for measuring the volume of ink droplets using a vision inspection technique, accurate contour detection is difficult because the outline becomes blurred due to the movement of the ink droplets. When exposure is performed using a single illumination per camera frame, the resulting image is often too dark, and therefore multiple exposures are frequently used. However, the contours of ink droplets captured through multiple exposures become even more blurred, making accurate contour detection difficult. Furthermore, because the apparent size of the ink droplets varies depending on the amount of light, there is a problem in that accurate volume calculation is difficult.

### Disclosure

### Technical Problem

7 Accordingly, the present disclosure has been made to address the above-described problems, and an object of the present disclosure is to provide a system and method for monitoring whether inkjet droplets are normally ejected using image registration accuracy, which enable rapid determination of whether a nozzle of an inkjet print head is defective by avoiding the use of complex image processing techniques such as contour extraction for calculating the volume of ink droplets.

### Technical Solution

8 In order to achieve the above object, according to one embodiment of the present disclosure, a system for monitoring normal ejection of inkjet droplets using image registration accuracy includes: one or more light strobes configured to irradiate light onto ink droplets falling from an inkjet print head installed in a reference system for acquiring reference image data and in a system to be inspected; a reference image data acquisition unit disposed opposite the one or more light strobes and configured to capture, at a predetermined cycle, ink droplets of an inkjet print head that is normally ejecting ink so as to acquire ink droplet image data; an inspection image data acquisition unit disposed opposite the one or more light strobes and configured to capture, at a predetermined cycle, ink droplets ejected from an inkjet print head to be inspected so as to acquire comparative ink droplet ejection image data; a first control unit configured to perform calibration of the reference image data acquisition unit and to store the ink droplet image data of the normally ejecting inkjet print head acquired by the reference image data acquisition unit as reference ink droplet image data; and a second control unit configured to perform calibration of the inspection image data acquisition unit, collect and store the comparative ink droplet ejection image data acquired by the inspection image data acquisition unit, and, when an overall registration value between the reference ink droplet image data and the comparative ink droplet ejection image data is less than a preset value, correct brightness, size, angle, and vertical and horizontal positions of the comparative ink droplet ejection image data using a correction tool so as to increase registration accuracy between the comparative ink droplet ejection image data and the reference ink droplet image data, wherein, when the registration accuracy is equal to or greater than the preset value after the correction is performed within a preset number of times, the second control unit performs a local comparison of image data within a preset ROI (Region of Interest) for each nozzle in the comparative ink droplet ejection image data and the reference ink droplet image data to determine whether ink droplet ejection is normal or abnormal, and wherein the second control unit determines a corresponding nozzle of the inkjet print head to be a normal nozzle when the registration accuracy is equal to or greater than a preset registration threshold, and determines the corresponding nozzle to be an abnormal nozzle when the registration accuracy is less than the preset registration threshold.

9 In the system for monitoring normal ejection of inkjet droplets using image registration accuracy according to the above-described embodiment, the reference image data acquisition unit and the inspection image data acquisition unit may be wide-field one-dimensional (1D) line-scan cameras configured to acquire ink droplet image data through multiple exposures per frame of the cameras, and more preferably, may acquire ink droplet image data using a single exposure per frame of the cameras.

In the system for monitoring normal ejection of inkjet droplets using image registration accuracy according to the above-described embodiment, the reference image data acquisition unit and the inspection image data acquisition unit may be two-dimensional (2D) area-scan cameras configured to acquire ink droplet image data through multiple exposures per frame of the cameras, and more preferably, may acquire ink droplet image data using a single exposure per frame of the cameras.

The system for monitoring normal ejection of inkjet droplets using image registration accuracy according to the above-described embodiment may further include a display unit configured to display a normal or abnormal result for a nozzle of the inkjet print head determined by the second control unit, and a registration accuracy between the reference ink droplet image data and the ink droplet ejection image data of the inkjet print head to be inspected.

In the system for monitoring normal ejection of inkjet droplets using image registration accuracy according to the above-described embodiment, the second control unit may be further configured such that, when an overall registration value between the reference ink droplet image data and the ink droplet ejection image data of the inkjet print head to be inspected is less than a preset value, the second control unit performs a correction operation on the comparative ink droplet ejection image data of the inkjet print head to be inspected within a preset number of iterations using a correction tool so that brightness, size, angle, and position thereof match those of the reference ink droplet image data as closely as possible, and calculates a registration accuracy between the reference ink droplet image data and the ink droplet ejection image data of the inkjet print head to be inspected.

In the system for monitoring normal ejection of inkjet droplets using image registration accuracy according to the above-described embodiment, the registration accuracy may be quantified by a registration tool, and the registration tool may use any one of a feature-based technique, an intensity-based technique, and a non-rigid registration technique. Various registration calculation techniques capable of calculating a registration accuracy between the reference image and the comparative image may also be used.

In order to achieve the above object, according to another embodiment of the present disclosure, a method for monitoring normal ejection of inkjet droplets includes: performing, by a first control unit of a reference system for acquiring reference image data, a calibration operation of a reference image data acquisition unit; collecting, by the first control unit, ink droplet image data of an inkjet print head that is normally ejecting ink, the ink droplet image data being captured by the reference image data acquisition unit, and storing the collected ink droplet image data as reference ink droplet image data; performing, by a second control unit of a system to be inspected, a calibration operation of an inspection image data acquisition unit; collecting, by the second control unit, comparative ink droplet image data of an inkjet print head to be inspected, the comparative ink droplet image data being captured by the inspection image data acquisition unit, and storing the collected ink droplet image data as comparative ink droplet image data; quantifying, by the second control unit, an overall registration state between the reference ink droplet image data and the comparative ink droplet image data of the inkjet print head to be inspected, and determining whether the quantified registration value is equal to or greater than a preset value; when the registration value is less than the preset value, correcting brightness, size, angle, and vertical and horizontal positions of the comparative ink droplet ejection image data of the inkjet print head to be inspected using a correction tool, thereby increasing registration accuracy between the comparative ink droplet ejection image data and the reference ink droplet image data; when the registration value is equal to or greater than the preset value, performing, by the second control unit, a local comparison of image data within a preset ROI (Region of Interest) for each nozzle in the reference ink droplet image data and the comparative ink droplet ejection image data; determining, by the second control unit, a corresponding nozzle to be a normal inkjet print head nozzle when the registration accuracy is equal to or greater than a preset registration threshold, and determining the corresponding nozzle to be an abnormal inkjet print head nozzle when the registration accuracy is less than the preset registration threshold; and displaying, through a display unit, the result determined in the determining step and the registration accuracy.

### Advantageous Effects

According to embodiments of the present disclosure, the system and method for monitoring normal ejection of inkjet droplets using image registration accuracy provide the following advantages. Calibration of a reference image data acquisition unit is performed, ink droplet image data of an inkjet print head that is normally ejecting ink and captured by the reference image data acquisition unit is collected, and the collected ink droplet image data is stored as reference ink droplet image data. Comparative ink droplet image data of an inkjet print head to be inspected, captured by an inspection image data acquisition unit, is then collected, and an overall registration value between the reference ink droplet image data and the comparative ink droplet image data is examined. When the overall registration value is less than a preset value, a correction tool is used to perform correction operations on brightness, size, angle, and vertical and horizontal positions of the comparative ink droplet image data within a preset number of iterations so that the comparative ink droplet image data matches those of the reference ink droplet image data. When the overall registration value exceeds a preset registration threshold, a local comparison is performed for ink droplets within a preset ROI for each nozzle using registration values, thereby determining whether ink droplet ejection is normal or abnormal. If the registration accuracy between the reference ink droplet image data and the comparative ink droplet image data within the preset ROI for each nozzle is less than the preset registration threshold, the corresponding nozzle is determined to be an abnormal inkjet print head nozzle. Accordingly, by determining whether a nozzle of an inkjet print head is defective without using complex image processing techniques, the system and method provide the significant advantage of enabling rapid determination of nozzle defects in the inkjet print head.

### DESCRIPTION OF DRAWINGS

FIG. 1 is a block diagram illustrating a system for monitoring normal ejection of inkjet droplets using image registration accuracy according to an embodiment of the present disclosure.

FIG. 2 is a flowchart illustrating a method for monitoring normal ejection of inkjet droplets using image registration accuracy according to an embodiment of the present disclosure.

FIG. 3 is a diagram illustrating that, when the reference image data acquisition unit or the inspection image data acquisition unit of FIG. 1 is a wide-field one-dimensional (1D) line-scan camera, non-uniform background illumination is made as uniform as possible through a calibration operation using a flat field correction (FFC) function.

FIG. 4 is a diagram illustrating that, when the reference image data acquisition unit or the inspection image data acquisition unit of FIG. 1 is a one-dimensional (1D) line-scan camera, ink droplet image data is acquired using a single exposure per camera frame.

FIG. 5 is a diagram illustrating that, when the reference image data acquisition unit or the inspection image data acquisition unit of FIG. 1 is a two-dimensional (2D) area-scan camera, ink droplet image data is acquired using a single exposure per camera frame.

FIG. 6 is a diagram illustrating that the first control unit of FIG. 1 collects ink droplet image data of an inkjet print head that is normally ejecting ink, captured by the reference image data acquisition unit, and stores the collected data as reference ink droplet image data.

FIG. 7 is a diagram illustrating that the second control unit of FIG. 1 collects ink droplet ejection image data of an inkjet print head to be inspected, captured by the inspection image data acquisition unit, and stores the collected data as comparative ink droplet image data.

FIG. 8 is an exemplary diagram illustrating ink droplet ejection image data (comparative ink droplet image data) of an inkjet print head to be inspected for registration with reference ink droplet image data.

FIG. 9 is a diagram illustrating a process of correcting brightness of comparative ink droplet image data using a correction tool so that the comparative ink droplet image data has the same brightness as reference ink droplet image data when the brightness of the reference ink droplet image data and the comparative ink droplet image data differs.

FIG. 10 is a diagram illustrating a process of correcting comparative ink droplet image data to have the same size as reference ink droplet image data by reducing or enlarging the comparative ink droplet image data when the sizes of the reference ink droplet image data and the comparative ink droplet image data differ.

FIG. 11 is a diagram illustrating a process of horizontally aligning the comparative ink droplet image data with the reference ink droplet image data by rotating the comparative ink droplet image data when the angles of the reference ink droplet image data and the comparative ink droplet image data differ.

FIG. 12 is a diagram illustrating a process of aligning comparative image data with reference ink droplet image data by horizontally or vertically shifting the comparative image data.

FIG. 13 is a diagram illustrating an example in which, when the reference image data acquisition unit or the inspection image data acquisition unit is a wide-field one-dimensional (1D) line-scan camera, the reference ink droplet image data and the comparative image data are well overlapped because a registration accuracy between them is equal to or greater than a preset registration threshold.

FIG. 14 is a diagram illustrating a case in which, when the reference image data acquisition unit or the inspection image data acquisition unit is a wide-field one-dimensional (1D) line-scan camera, the reference ink droplet image data and the comparative image data are not properly overlapped because a registration accuracy between them is less than a preset registration threshold.

FIG. 15 is a diagram illustrating reference ink droplet image data and comparative image data when the reference image data acquisition unit or the inspection image data acquisition unit is a two-dimensional (2D) area-scan camera.

FIG. 16 is a diagram illustrating a state in which comparative ink droplet image data and reference ink droplet image data are overlapped after completion of brightness, size, angle, and vertical and horizontal position correction operations when the reference image data acquisition unit or the inspection image data acquisition unit is a two-dimensional (2D) area-scan camera.

FIG. 17 is a diagram illustrating a case in which reference ink droplet image data and comparative image data are well registered, resulting in a registration accuracy close to 100%, for example, 99.5%.

FIG. 18 is a diagram illustrating a case in which a registration accuracy between reference ink droplet image data and comparative image data is 82%.

FIG. 19 is a diagram illustrating quantification of ink droplet image registration accuracy for corresponding ROIs after setting a region of interest (ROI) for each nozzle of the inkjet print head.

FIG. 20 is a diagram illustrating an example in which one or a plurality of ROIs are set for each nozzle of the inkjet print head, and one or more ink droplet shapes are included within each ROI.

### DETAILED DESCRIPTION

In describing embodiments of the present disclosure, detailed descriptions of well-known technologies related to the present disclosure may be omitted when it is determined that such descriptions could unnecessarily obscure the gist of the present disclosure. The terminology used herein is defined in consideration of the functions of the present disclosure and may vary depending on the intent or practice of users or operators. Accordingly, the definitions of such terms should be understood based on the overall contents of this specification. The terms used in the detailed description are intended only to describe embodiments of the present disclosure and should not be construed as limiting. Unless clearly indicated otherwise, expressions in the singular form include the plural meaning. As used herein, expressions such as “include” or “comprise” are intended to specify the presence of stated features, numbers, steps, operations, elements, or combinations thereof, and should not be interpreted as excluding the presence or possibility of one or more other features, numbers, steps, operations, elements, or combinations thereof in addition to those described.

In the systems illustrated in the drawings, elements shown in some instances may be represented with the same reference numerals or with different reference numerals, suggesting that the elements may be identical or similar. However, the elements may have different implementations and may operate with some or all of the systems shown or described in this specification. Various elements illustrated in the drawings may be the same or different. The designation of which element is referred to as a first element and which is referred to as a second element is arbitrary.

As used herein, when one component is described as “transmitting,” “delivering,” or “providing” data or a signal to another component, it includes not only direct transmission of the data or signal from one component to another, but also transmission of the data or signal to the other component through at least one additional component.

Hereinafter, embodiments of the present disclosure will be described in detail with reference to the accompanying drawings.

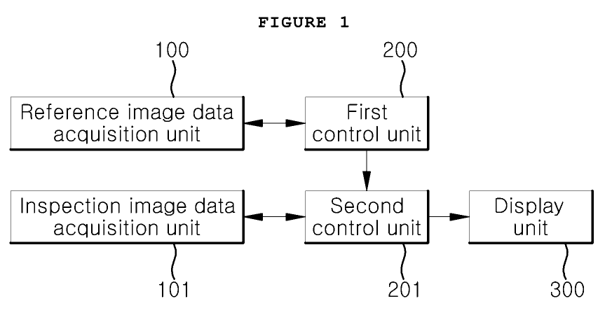

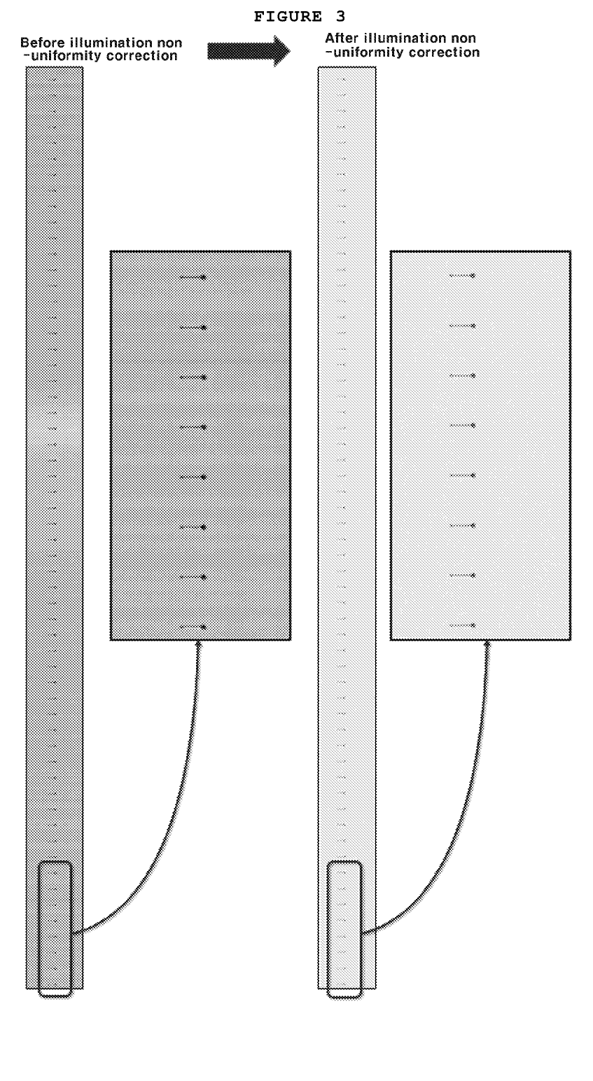

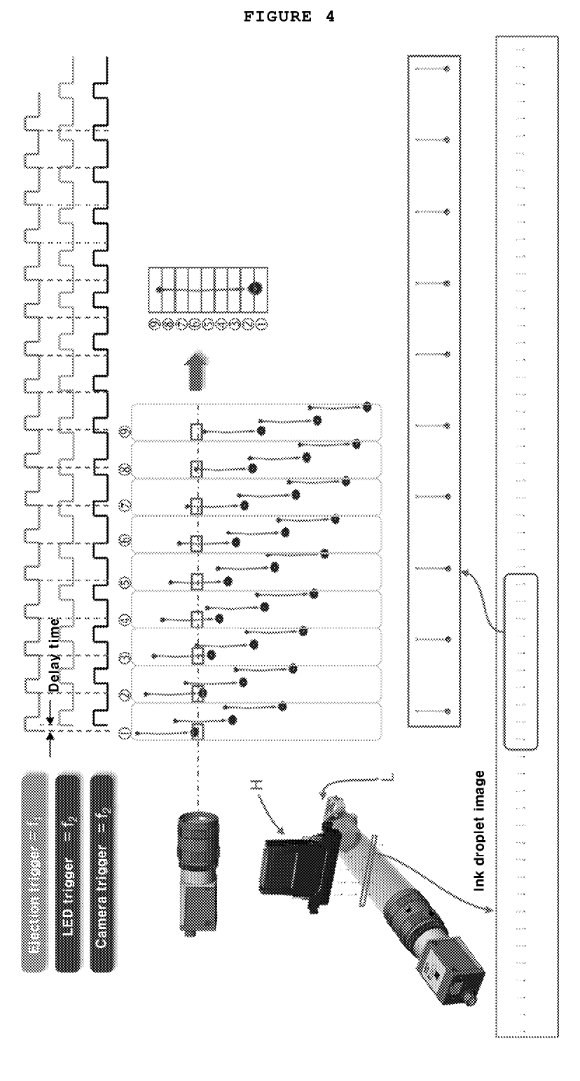

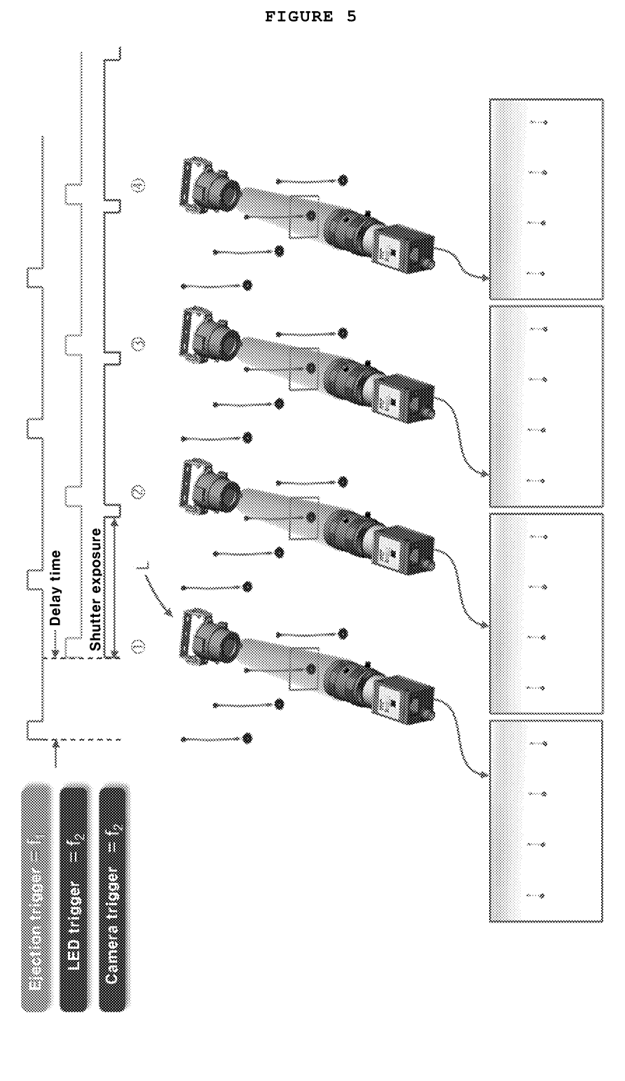

FIG. 1 is a block diagram illustrating a system for monitoring normal ejection of inkjet droplets using image registration accuracy according to an embodiment of the present disclosure, FIG. 3 illustrates that, when the reference image data acquisition unit or the inspection image data acquisition unit of FIG. 1 is a wide-field one-dimensional (1D) line-scan camera, non-uniform background illumination is made as uniform as possible through a calibration operation using a flat field correction (FFC) function, FIG. 4 illustrates that, when the reference image data acquisition unit or the inspection image data acquisition unit of FIG. 1 is a one-dimensional (1D) line-scan camera, ink droplet image data is acquired using a single exposure per camera frame, FIG. 5 illustrates that, when the reference image data acquisition unit or the inspection image data acquisition unit of FIG. 1 is a two-dimensional (2D) area-scan camera, ink droplet image data is acquired using a single exposure per camera frame.

According to an embodiment of the present disclosure, a system for monitoring normal ejection of inkjet droplets using image registration accuracy includes, as illustrated in FIGS. 1 and 3 to 5, a light strobe (L), a reference image data acquisition unit (100), a first control unit (200), an inspection image data acquisition unit (101), a second control unit (201), and a display unit (300). Each of the first control unit (200) and the second control unit (201) may be a hardware processor such as a CPU. The display unit (300) may be a hardware display device.

The light strobe (L) is configured to irradiate light onto ink droplets falling from an inkjet print head (H) installed in a reference system (a system used for acquiring reference image data) and in a system to be inspected. For example, as illustrated in FIGS. 4 and 5, the light strobe (L) is disposed below and behind the inkjet print head (H) so as to irradiate light onto the ink droplets, thereby enabling the reference image data acquisition unit (100) or the inspection image data acquisition unit (101), which is disposed opposite the light strobe (L), to capture one-dimensional (1D) or two-dimensional (2D) images of the ink droplets falling from the inkjet print head (H).

The light strobe (L) may be configured as a cluster composed of one or more high-luminance LEDs or as a laser excited phosphor (LEP), and may be capable of overdriving, in which the light strobe is driven at a current higher than a normal operating current in order to provide very high luminance during an extremely short flashing duration.

The reference image data acquisition unit (100) or the inspection image data acquisition unit (101) is disposed opposite the light strobe (L) and is configured to capture ink droplets at a predetermined cycle to acquire ink droplet image data. The reference image data acquisition unit (100) or the inspection image data acquisition unit (101) may employ a wide-field one-dimensional (1D) line-scan camera or a two-dimensional (2D) area-scan camera. Here, the reference image data acquisition unit (100) is used for acquiring reference image data, and the inspection image data acquisition unit (101) is installed in the system to be inspected for acquiring image data to be inspected. However, a single image data acquisition unit may also be used to acquire both the reference image data and the image data to be inspected.

The wide-field one-dimensional (1D) line-scan camera is disposed opposite the light strobe (L) through a lens and a lens barrel for the wide-field 1D line-scan camera, and is configured to capture ink droplets at a predetermined cycle to acquire high-resolution one-dimensional (1D) ink droplet image data. When a wide-field 1D line-scan camera is used, in order to acquire ink droplet image data of falling ink droplets using a single exposure per camera frame, an ultra-high-luminance light strobe capable of supplying a sufficient amount of light to the image sensor of the camera even during an ultra-short pulse (illumination duration of the light strobe) of sub-microseconds, and more preferably 500 ns or less, should be used. It is preferable to use a light strobe employing ultra-high-luminance LEDs or LED clusters capable of operating at a current higher than a normal operating current, i.e., capable of overdriving, a laser excited phosphor (LEP), or a combination thereof.

The wide-field one-dimensional (1D) line-scan camera is capable of simultaneously measuring ink droplets ejected from a significantly greater number of nozzles at high speed compared to a two-dimensional (2D) area-scan camera. Unlike a 2D area-scan camera, which captures a two-dimensional image of length and width at a specific point in time, the wide-field 1D line-scan camera measures how the width of ink droplets changes over a predetermined time cycle. Using the imaged information, precise relative comparison of ink droplets ejected from the nozzles is possible.

The two-dimensional (2D) area-scan camera is configured to acquire shape image data of ink droplets at a specific point in time. The 2D area-scan camera receives light through a lens for the 2D area-scan camera to capture images of the ink droplets. The 2D area-scan camera may acquire ink droplet image data using a single exposure per camera frame. Similarly, it is preferable to use an ultra-high-luminance light strobe capable of operating at an ultra-short pulse of 500 ns or less.

The shape image data of the ink droplets acquired at a specific point in time by the two-dimensional (2D) area-scan camera provides information on a two-dimensional plane including length and width.

The first control unit (200) performs calibration operations for the reference image data acquisition unit (100), including adjustments related to brightness level, illumination uniformity, magnification, focus, scaling between image pixels and physical length, and nozzle position and angle of the inkjet print head (H). The first control unit (200) also collects ink droplet image data of the inkjet print head (H) that is normally ejecting ink, captured by the reference image data acquisition unit (100), stores the collected ink droplet image data as reference ink droplet image data, and provides the stored data to the second control unit (201).

The second control unit (201) is a microcomputer configured to control the overall components. The second control unit (201) performs calibration operations for the inspection image data acquisition unit (101), including adjustments related to brightness level, illumination uniformity, magnification, focus, scaling between image pixels and physical length, and nozzle position and angle of the inkjet print head (H). The second control unit (201) collects comparative ink droplet ejection image data of the inkjet print head (H) to be inspected, captured by the inspection image data acquisition unit (101). When an overall registration value between the reference ink droplet image data provided by the first control unit (200) and the comparative ink droplet ejection image data of the inkjet print head (H) to be inspected is less than a preset value, the second control unit (201) may preferentially perform a correction operation within a preset number of iterations using a correction tool (for example, a commonly used processing tool) so that the comparative ink droplet ejection image data matches the brightness, size, angle, and position of the reference ink droplet image data as closely as possible. When the registration accuracy after correction is equal to or greater than the preset value, the second control unit (201) performs a local comparison between image data within a preset ROI (Region of Interest) for each nozzle in the comparative ink droplet ejection image data of the inkjet print head (H) to be inspected and image data within a preset ROI for each nozzle in the reference ink droplet image data, thereby determining whether ink droplet ejection is normal or abnormal.

The second control unit (201) quantifies a registration accuracy between the stored reference ink droplet image data and comparative ink droplet ejection image data (comparative ink droplet image data) of the inkjet print head (H) to be inspected using a registration tool. For example, when MATLAB is used as the registration tool, any one of a feature-based technique, an intensity-based technique, and a non-rigid registration technique may be employed. Other tools capable of calculating and quantifying differences between two images may also be used. The second control unit (201) determines a corresponding nozzle of the inkjet print head to be a normal nozzle when the registration value is equal to or greater than a preset value, and determines the corresponding nozzle to be an abnormal nozzle when the registration value is less than the preset registration threshold.

The display unit (300) is configured to display a normal or abnormal result for a nozzle of the inkjet print head as determined by the second control unit (201), and a registration accuracy between the reference ink droplet image data and the comparative ink droplet ejection image data of the inkjet print head to be inspected.

A method for monitoring normal ejection of inkjet droplets using the system for monitoring normal ejection of inkjet droplets based on image registration accuracy according to an embodiment of the present disclosure will now be described.

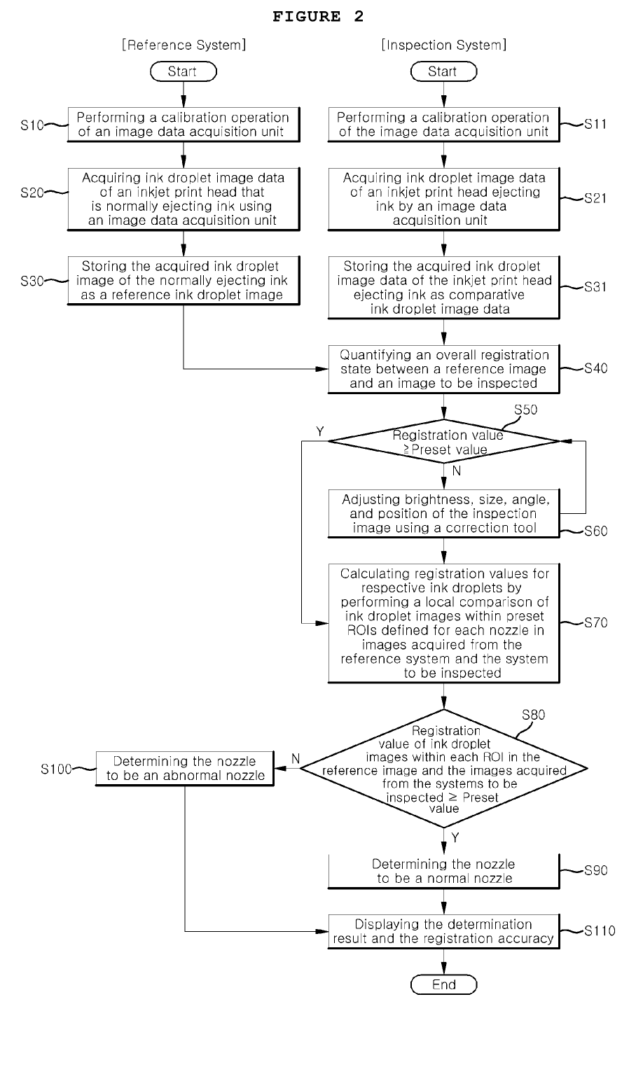

FIG. 2 is a flowchart illustrating a method for monitoring normal ejection of inkjet droplets using image registration accuracy according to an embodiment of the present disclosure, wherein “S” denotes a step.

First, the first control unit (200) performs a calibration operation on the reference image data acquisition unit (100) (S10). FIG. 3 illustrates a calibration operation in which non-uniform background illumination is made as uniform as possible using a flat field correction (FFC) function when the reference image data acquisition unit (100) or the inspection image data acquisition unit (101) of FIG. 1 is a wide-field one-dimensional (1D) line-scan camera. The calibration operation may include adjusting a brightness level, magnification, focus, scaling between image pixels and physical length, and nozzle position and angle of the inkjet print head (H) for the reference image data acquisition unit (100) or the inspection image data acquisition unit (101).

Next, the first control unit (200) collects ink droplet image data of the inkjet print head (H) that is normally ejecting ink, captured by the reference image data acquisition unit (100) (S20), and stores the collected ink droplet image data as reference ink droplet image data (S30).

FIG. 4 illustrates that, when the reference image data acquisition unit (100) or the inspection image data acquisition unit (101) of FIG. 1 is a one-dimensional (1D) line-scan camera, ink droplet image data is acquired using a single exposure per camera frame after a calibration operation is performed by the first control unit (200) or the second control unit (201).

FIG. 5 illustrates that, when the reference image data acquisition unit (100) or the inspection image data acquisition unit (101) of FIG. 1 is a two-dimensional (2D) area-scan camera, ink droplet image data is acquired.

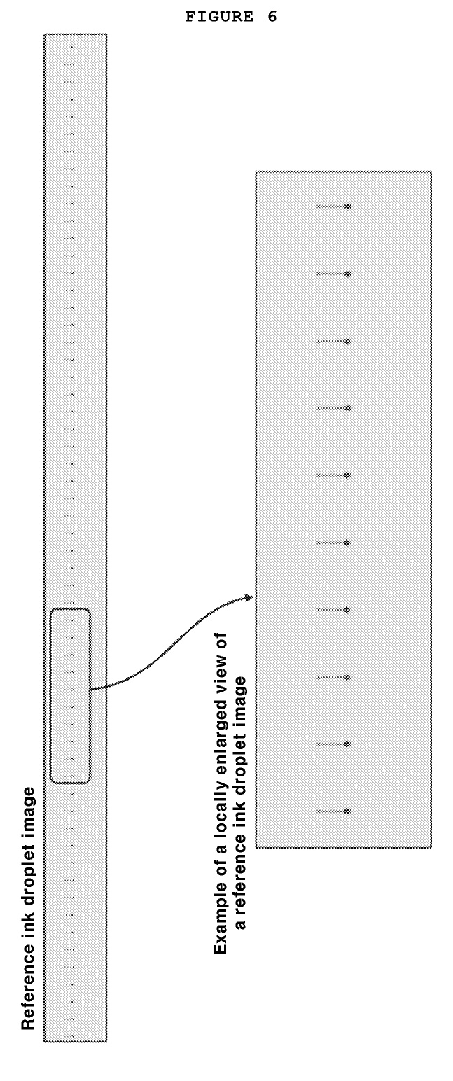

FIG. 6 illustrates that the first control unit (200) of FIG. 1 collects ink droplet image data of an inkjet print head (H) that is normally ejecting ink, captured by the reference image data acquisition unit (100), and stores the collected data as reference ink droplet image data.

The second control unit (201) of the system to be inspected may perform a calibration operation on the inspection image data acquisition unit (101) (S11). Next, the second control unit (201) of the system to be inspected collects comparative ink droplet ejection image data of the inkjet print head (H) to be inspected, captured by the inspection image data acquisition unit (101) (S21).

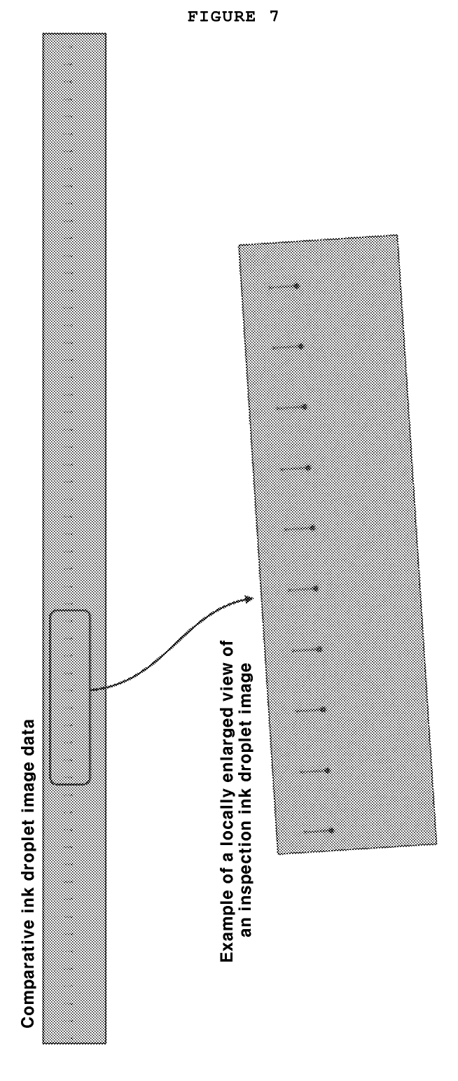

FIG. 7 illustrates that the second control unit (201) of the system to be inspected in FIG. 1 collects ink droplet image data of the inkjet print head (H), captured by the inspection image data acquisition unit (101), and stores the collected data as comparative ink droplet image data (S31).

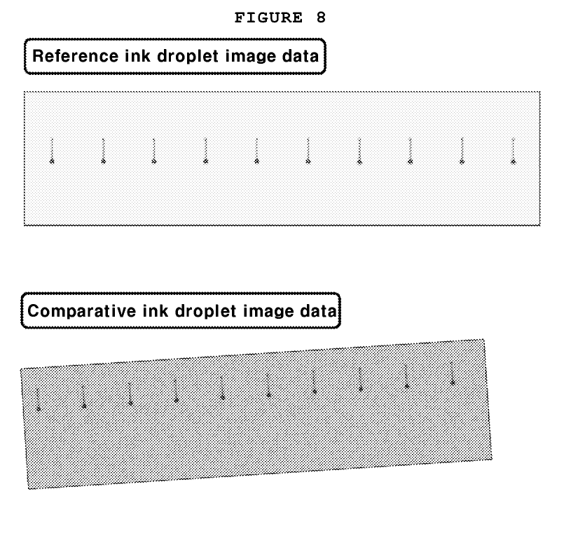

FIG. 8 is a comparative diagram illustrating reference ink droplet image data stored by the first control unit (200) of the reference system and comparative ink droplet ejection image data (comparative ink droplet image data) of the inkjet print head (H) to be inspected, captured by the image data acquisition unit (101) and provided to the second control unit (201) of the system to be inspected.

Next, the second control unit (201) of the system to be inspected quantifies a registration state between the reference ink droplet image data and the ink droplet ejection image data of the inkjet print head (H) to be inspected (S40), and determines whether the quantified registration value is equal to or greater than a preset value (S50).

In step (S50), when the registration value is less than the preset value (N), the second control unit (201) of the system to be inspected may perform a correction operation on the comparative ink droplet ejection image data so that the comparative ink droplet ejection image data matches the reference ink droplet image data as closely as possible (S60). That is, when brightness, size, angle, and position of the comparative ink droplet image data differ from those of the reference ink droplet image data due to differences between the inspection image data acquisition unit (101), which acquires the comparative ink droplet image data of the inkjet print head (H) to be inspected, and the reference image data acquisition unit (100), which acquires the reference ink droplet image data, or due to differences in imaging conditions, the second control unit (201) may correct the comparative ink droplet image data of the inkjet print head (H) to be inspected within a preset number of iterations using a correction tool so as to be suitable for a subsequent registration calculation operation.

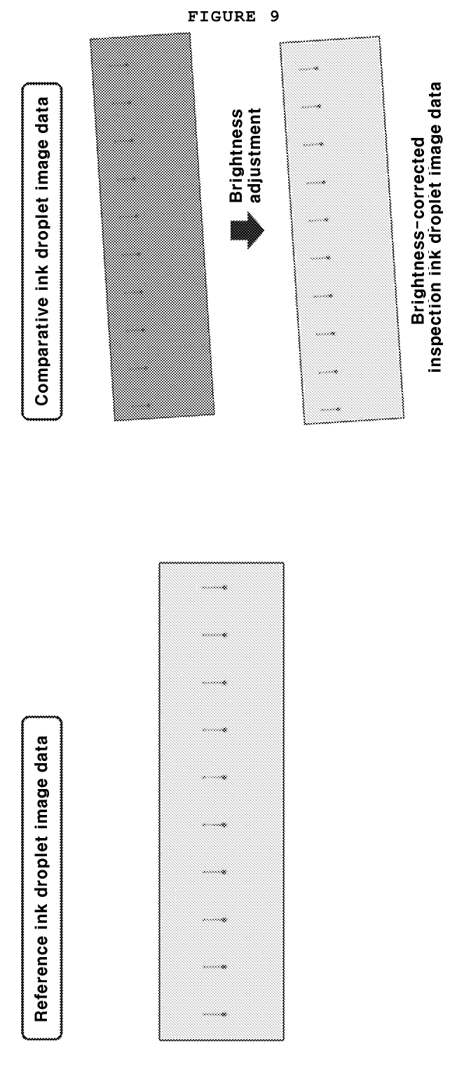

FIG. 9 is an exemplary diagram illustrating an operation of correcting brightness of comparative ink droplet ejection image data (comparative ink droplet image data) of the inkjet print head (H) to be inspected, stored by the second control unit (201) of the system to be inspected, so that the brightness is as similar as possible to that of the reference ink droplet image data.

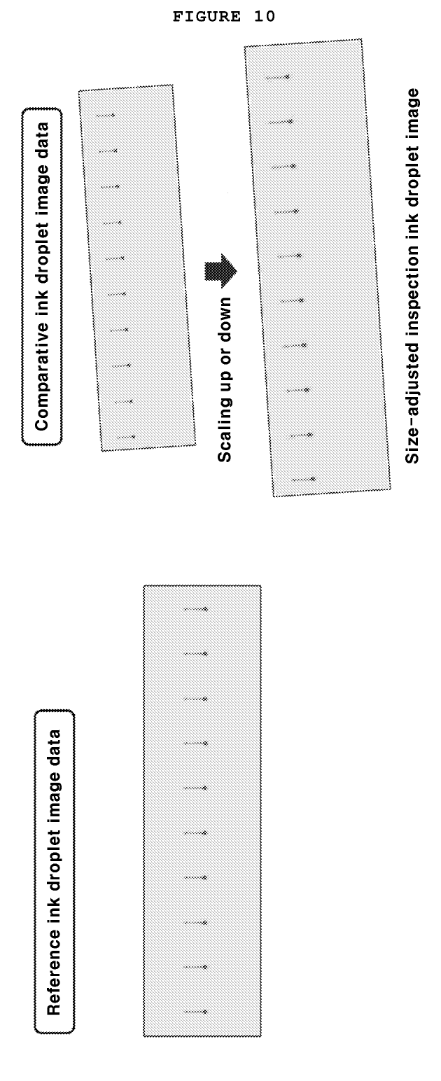

FIG. 10 is a diagram illustrating an operation of correcting the size of comparative ink droplet ejection image data of the inkjet print head (H) to be inspected by the second control unit (201) of the system to be inspected so that the size matches that of the reference ink droplet image data through image enlargement or reduction. At this time, it is preferable not only to match the size of the image but also to match the number of horizontal and vertical pixels constituting the image.

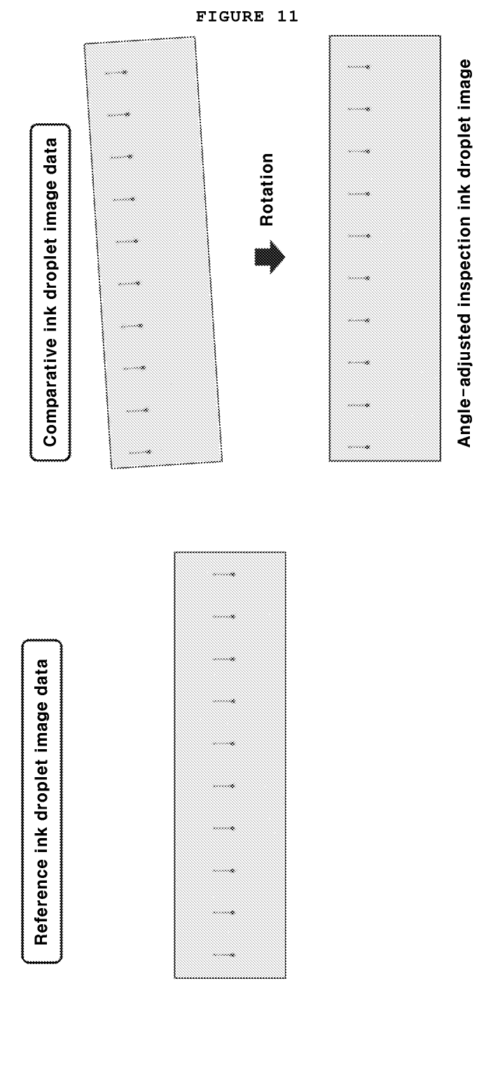

FIG. 11 is a diagram illustrating a process in which the second control unit (201) of the system to be inspected horizontally aligns comparative ink droplet ejection image data of the inkjet print head (H) to be inspected with the reference ink droplet image data through rotation.

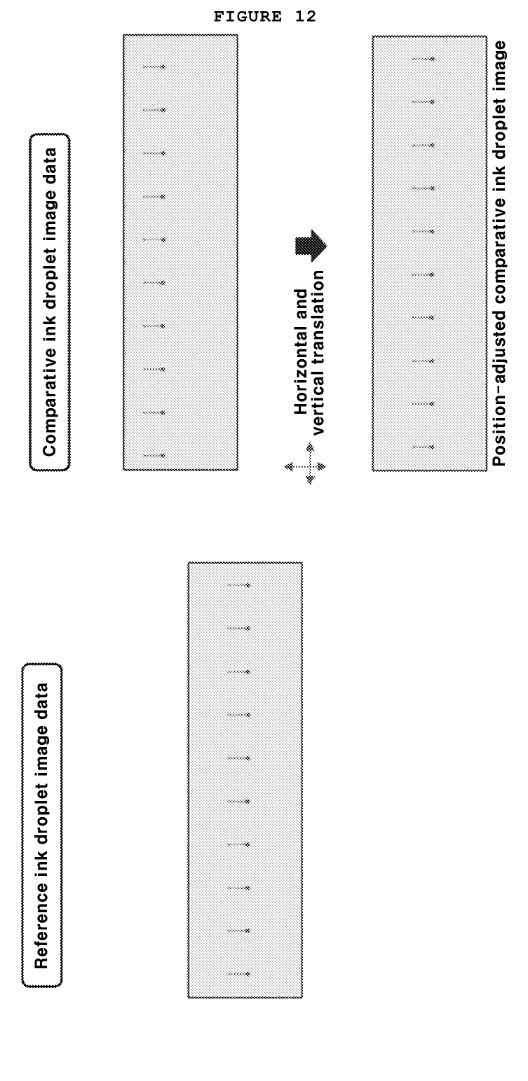

FIG. 12 is a diagram illustrating a process in which the second control unit (201) of the system to be inspected aligns comparative ink droplet ejection image data of the inkjet print head (H) to be inspected with the reference ink droplet image data through horizontal or vertical shifting.

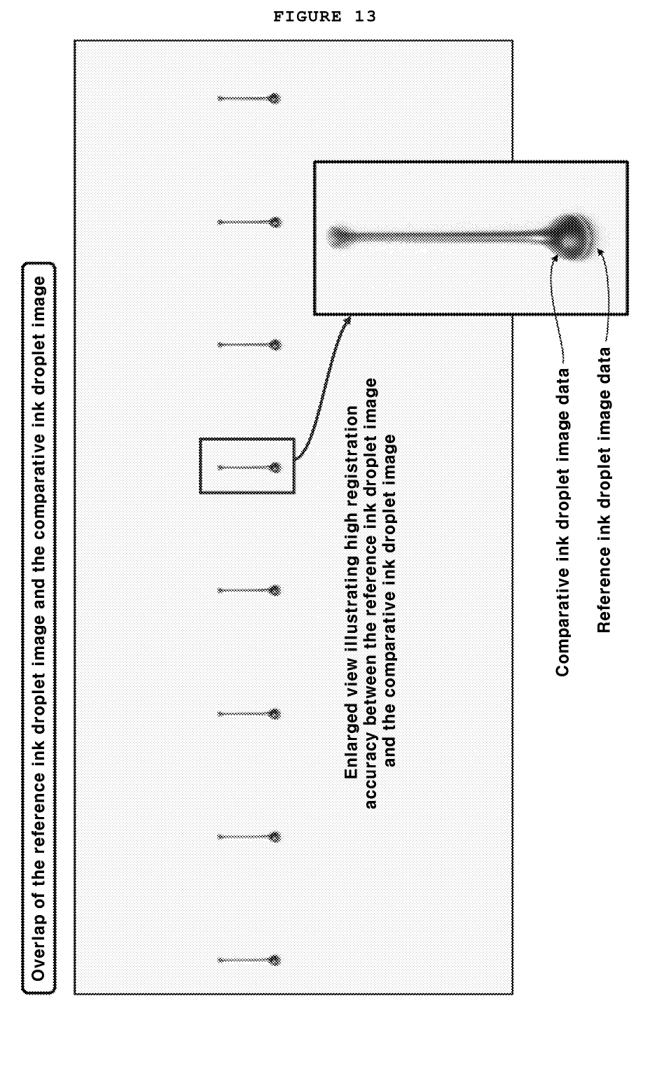

FIG. 13 is a diagram illustrating a state in which, when the reference image data acquisition unit (100) or the inspection image data acquisition unit (101) is a wide-width one-dimensional (1D) line scan camera, the reference ink droplet image data and the comparative image data are well overlapped because the registration accuracy is equal to or greater than a preset registration threshold.

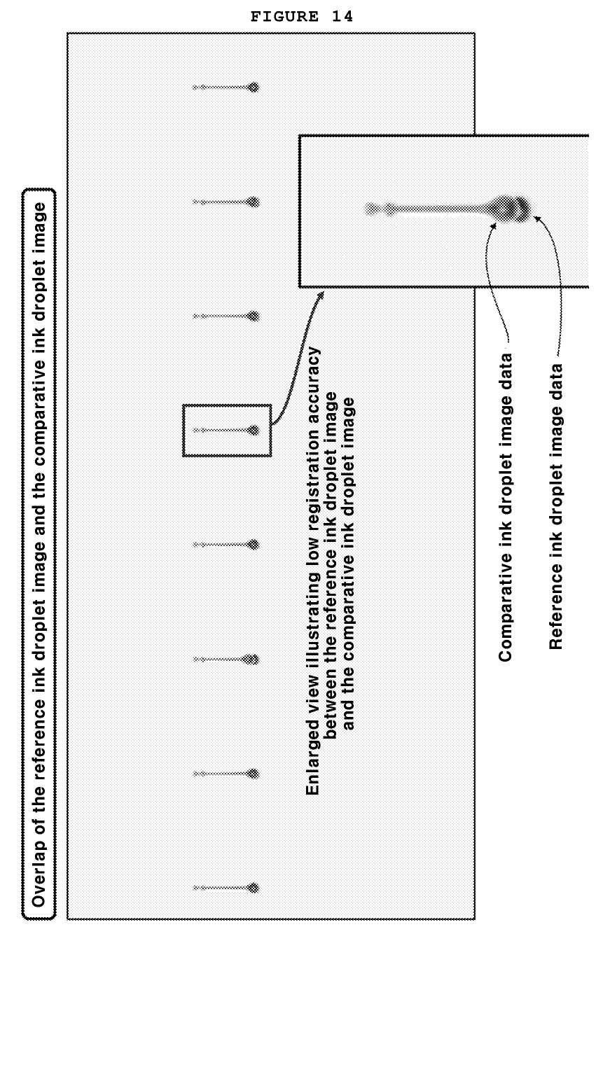

FIG. 14 is a diagram illustrating a state in which, when the reference image data acquisition unit (100) or the inspection image data acquisition unit (101) is a wide-width one-dimensional (1D) line scan camera, the reference ink droplet image data and the comparative image data are not properly overlapped because the registration accuracy is less than a preset registration threshold.

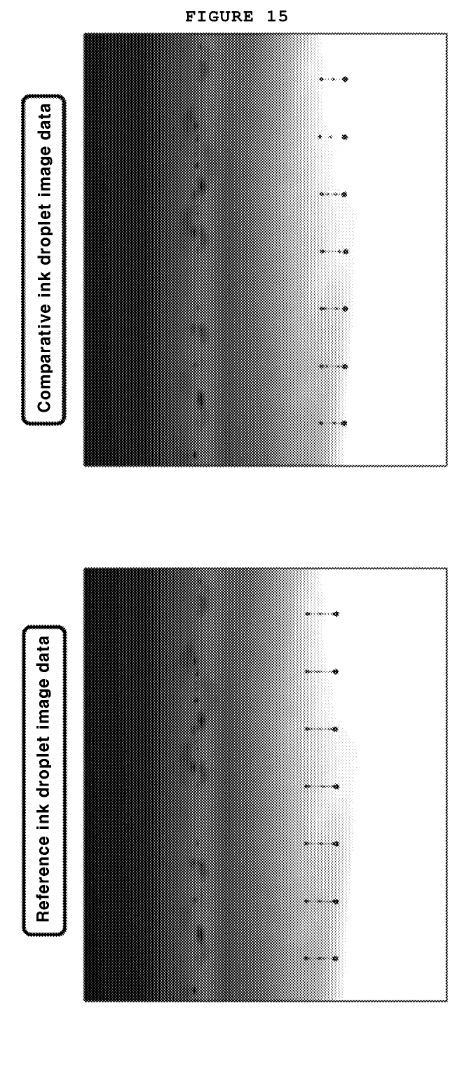

FIG. 15 is a diagram illustrating the reference ink droplet image data and, when the reference image data acquisition unit (100) or the inspection image data acquisition unit (101) is a two-dimensional (2D) area scan camera, the comparative ink droplet image data after performing correction operations on brightness, size, angle, and position through horizontal and vertical shifting, similar to the case of the wide-width one-dimensional (1D) line scan camera.

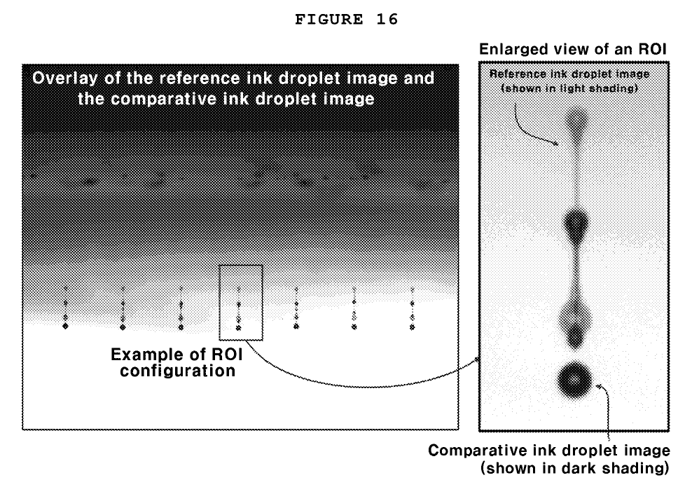

FIG. 16 is a diagram illustrating a situation in which, when the reference image data acquisition unit (100) or the inspection image data acquisition unit (101) is a two-dimensional (2D) area scan camera, the reference ink droplet image data and the comparative image data do not properly overlap even after correction operations have been performed through adjustments in brightness, size, angle, and horizontal and vertical shifting.

Through the correction operation performed by the second control unit (201) of the system to be inspected, the comparative ink droplet ejection image data of the inkjet print head (H) to be inspected is corrected within a preset number of times so as to match the reference ink droplet image data. If the registration accuracy between the reference ink droplet image data and the comparative ink droplet image data remains below a preset value even after the correction operation, a registration mismatch determination is made and subsequent operations are halted. Possible causes of such a registration mismatch at this stage may include differences between the image acquisition systems, significant differences in imaging conditions, or substantially abnormal ejection of ink droplets.

Meanwhile, in step (S50), when the registration accuracy between the reference ink droplet image data and the ink droplet ejection image data of the inkjet print head (H) to be inspected is equal to or greater than a preset value (Y), the process proceeds to step (S70).

In step (S70), the second control unit (201) calculates the registration accuracy of ink droplets for each nozzle by performing a local comparison between image data within a preset ROI for each nozzle in the reference ink droplet image data and image data within a preset ROI for each nozzle in the comparative ink droplet image data of the inkjet print head (H) to be inspected. By performing the local comparison within the preset ROI for each nozzle, rather than comparing the registration accuracy using the entire images of the reference ink droplet image data and the comparative ink droplet image data, image processing time can be reduced and differences between ink droplets can be quantified more accurately. In this case, one ROI is generally set for each nozzle; however, multiple ROIs may be set as needed.

Next, the second control unit (201) of the system to be inspected determines whether the registration accuracy calculated in step (S70) is equal to or greater than a preset registration threshold (S80). In step (S80), when the registration accuracy is equal to or greater than the preset registration threshold (Y), the second control unit (201) of the system to be inspected determines the corresponding nozzle to be a normal inkjet print head nozzle (S1090). Conversely, when the registration accuracy is less than the preset registration threshold (N), the second control unit (201) determines the corresponding nozzle to be an abnormal inkjet print head nozzle (S1200).

Next, the second control unit (201) of the system to be inspected displays, through the display unit (301) of the system to be inspected, the result determined as a normal inkjet print head nozzle in step (S90) or the result determined as an abnormal inkjet print head nozzle in step (S100), along with the registration accuracy value, the reference droplet image data, and the comparative ink droplet image data (S110).

Meanwhile, in implementing the present invention, the calibration steps (S10 and S11) for the reference image data acquisition unit (100) and the inspection image data acquisition unit (101), the step (S40) of quantifying an overall registration value between the reference ink droplet image data and the comparative ink droplet image data of the inkjet print head (H) to be inspected, the step (S50) of comparing the registration value with a preset registration threshold, and the step (S60) of correcting the comparative ink droplet image data of the inkjet print head (H) to be inspected may be omitted when unnecessary.

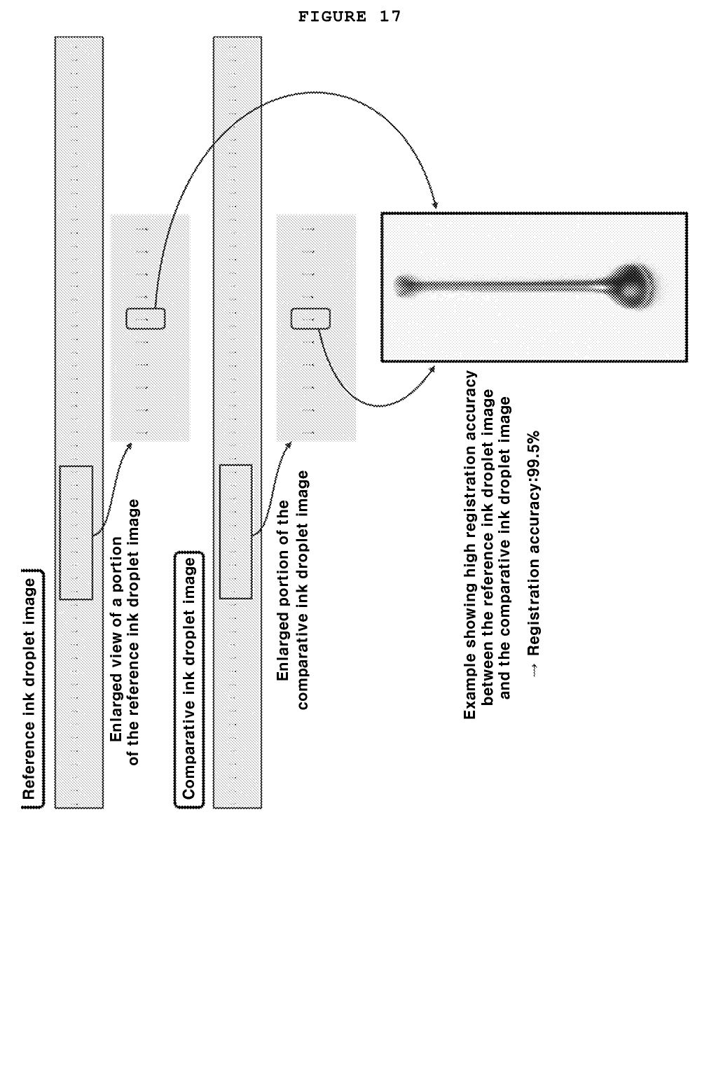

FIG. 17 is a diagram illustrating an example in which the registration accuracy between the reference ink droplet image data and the comparative image data is 99.5%.

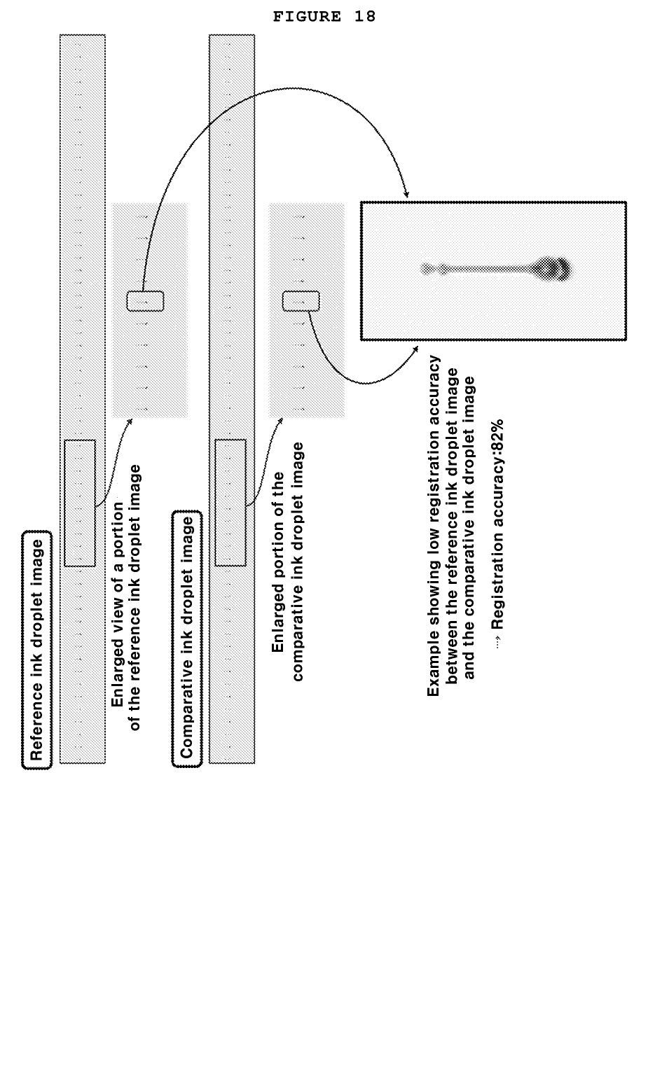

FIG. 18 is a diagram illustrating an example in which the registration accuracy between the reference ink droplet image data and the comparative image data is 82%.

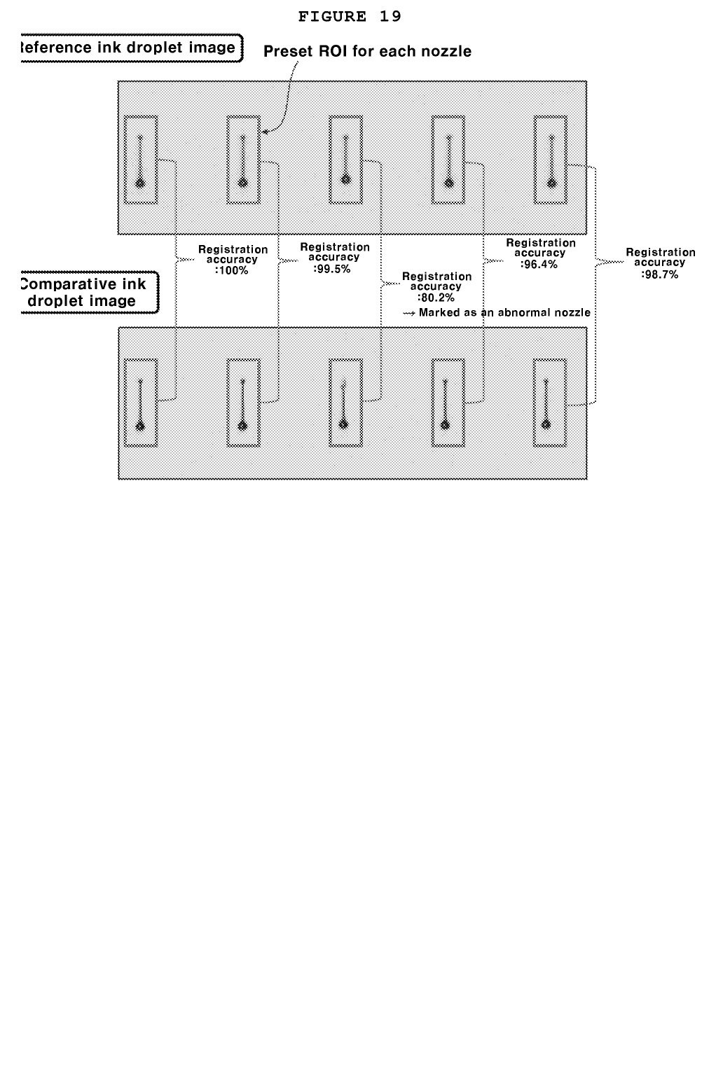

FIG. 19 is a diagram illustrating an example of quantifying the registration accuracy of reference and comparative ink droplet image data for each corresponding ROI after setting a Region Of Interest (ROI) for each nozzle of the inkjet print head (H).

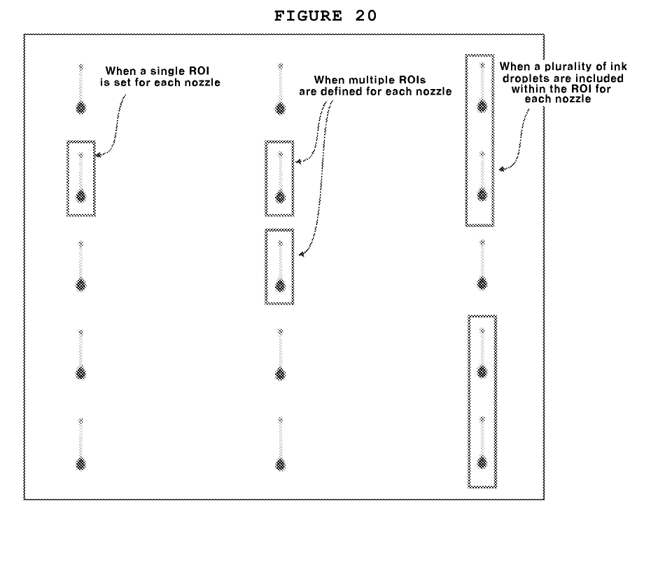

In this case, because image processing is performed to execute a local comparison within the ROI set for each nozzle rather than performing a registration inspection on the entire reference ink droplet image and the comparative ink droplet image, the time required to calculate the registration value can be reduced. Further, when a registration inspection is performed on the entire reference ink droplet image and the comparative ink droplet image, margins occupying a significant portion of the images may be determined to have a high registration accuracy, such that the final registration value may remain high even if the shapes of the reference ink droplet image and the comparative ink droplet image differ. In contrast, when the local comparison is performed within the ROI set for each nozzle, the influence of the margins on the registration value can be minimized, thereby improving the accuracy in determining whether each nozzle is normal or abnormal. In this regard, although one ROI is generally set for each nozzle, a plurality of ROIs may be set as necessary, as illustrated in FIG. 20, and one or more ink droplets may be included within a single ROI. When a plurality of ROIs are set for each nozzle, the registration accuracy of the ink droplets may be an average of the registration values of the respective ROIs for each nozzle.

The registration accuracy may be determined to indicate an abnormal nozzle when it is, for example, less than 82%.

According to the system and method for monitoring normal ejection of inkjet ink droplets using image registration accuracy according to an embodiment of the present invention, a calibration operation of the reference image data acquisition unit is performed, ink droplet image data of an inkjet print head that is normally ejecting ink captured by the reference image data acquisition unit is collected, and the collected ink droplet image data is stored as reference ink droplet image data. Comparative ink droplet image data of an inkjet print head to be inspected captured by the inspection image data acquisition unit is collected, and an overall registration value between the reference ink droplet image data and the comparative ink droplet image data is evaluated. When the overall registration value is less than a preset value, a correction operation on brightness, size, angle, and vertical and horizontal positions of the comparative ink droplet image data is performed within a preset number of times using a correction tool so that the comparative ink droplet image data matches the brightness, size, angle, and vertical and horizontal positions of the reference ink droplet image data. When the overall registration value between the reference ink droplet image data and the comparative ink droplet image data is greater than a preset registration threshold, a local comparison is performed using registration values of ink droplets within ROIs set for each nozzle to determine whether ink droplet ejection is normal or abnormal. If the registration accuracy between the reference ink droplet image data and the comparative ink droplet image data within the ROI set for each nozzle is less than the preset registration threshold, the corresponding nozzle is determined to be an abnormal inkjet print head nozzle. Accordingly, it is possible to rapidly determine whether a nozzle of the inkjet print head is defective without using complex image processing.

Although the preferred embodiments have been disclosed in the drawings and specification, and specific terms have been used, such terms are employed solely for the purpose of describing the embodiments of the present invention and are not intended to limit the meaning of the invention or restrict the scope of the invention as set forth in the appended claims. Accordingly, those having ordinary skill in the art will appreciate that various modifications and equivalent embodiments may be made without departing from the spirit of the invention. Therefore, the true technical scope of protection of the present invention should be determined by the technical spirit of the appended claims.

### Explanation of Reference Numerals

H: Inkjet print head

L: Light strobe composed of an LED or LEP

100: Reference image data acquisition unit

101: Inspection image data acquisition unit

200: First control unit

201: Second control unit

300: Display unit

### Industrial Applicability

The present invention is applicable to the field of monitoring whether inkjet ink droplets are normally ejected, in which image registration accuracy is used without employing complex image processing such as contour extraction for calculating the volume of ink droplets, thereby enabling rapid determination of nozzle defects in an inkjet print head.

1. A system for monitoring normal ejection of inkjet ink droplets using image registration accuracy, the system comprising:
one or more light strobes (L) configured to irradiate light onto ink droplets falling from an inkjet print head (H) installed in a reference system for acquiring reference image data and in a system to be inspected;
a reference image data acquisition unit (100) disposed opposite to the light strobes and configured to capture, at a predetermined cycle, ink droplets of the inkjet print head that is normally ejecting ink so as to acquire ink droplet image data;
an inspection image data acquisition unit (101) disposed opposite to the light strobes and configured to capture, at a predetermined cycle, ink droplets ejected from the inkjet print head to be inspected so as to acquire comparative ink droplet ejection image data;
a first control unit (200) configured to perform calibration of the reference image data acquisition unit and to store the ink droplet image data of the normally ejecting inkjet print head acquired by the reference image data acquisition unit as reference ink droplet image data; and
a second control unit (201) configured to perform calibration of the inspection image data acquisition unit, to collect and store the comparative ink droplet ejection image data of the inkjet print head to be inspected acquired by the inspection image data acquisition unit, and to correct brightness, size, angle, and vertical and horizontal positions of the comparative ink droplet ejection image data using a correction tool when an overall registration value between the reference ink droplet image data and the comparative ink droplet ejection image data is less than a preset value, thereby increasing a registration accuracy between the comparative ink droplet ejection image data and the reference ink droplet image data, wherein, when the registration accuracy is equal to or greater than the preset value after the correction is performed within a preset number of times, a local comparison of image data within a preset ROI (Region of Interest) for each nozzle in the comparative ink droplet ejection image data and the reference ink droplet image data is performed to determine whether ink droplet ejection is normal or abnormal, and wherein a corresponding nozzle of the inkjet print head is determined to be a normal nozzle when the registration accuracy is equal to or greater than a set registration threshold, and is determined to be an abnormal nozzle when the registration accuracy is less than the set registration threshold.

2. The system of claim 1, wherein the reference image data acquisition unit (100) and the inspection image data acquisition unit (101) are wide-width one-dimensional (1D) line scan cameras, and wherein ink droplet image data is acquired using a single exposure per frame of the cameras.

3. The system of claim 1, wherein the reference image data acquisition unit (100) and the inspection image data acquisition unit (101) are two-dimensional (2D) area scan cameras, and wherein ink droplet image data is acquired using a single exposure per frame of the cameras.

4. The system of claim 1, wherein the reference image data acquisition unit (100) and the inspection image data acquisition unit (101) are two-dimensional (2D) area scan cameras, and wherein ink droplet image data is acquired using multiple exposures per frame of the cameras.

5. The system of claim 1, further comprising: a display unit (300) configured to display a normal or abnormal result for a nozzle of the inkjet print head determined by the second control unit (201), and a registration accuracy between the reference ink droplet image data and the comparative ink droplet ejection image data of the inkjet print head to be inspected.

6. The system of claim 1, wherein the second control unit (201) is further configured to, when an overall registration value between the reference ink droplet image data and the ink droplet ejection image data of the inkjet print head to be inspected is less than a preset value, perform a correction operation on the comparative ink droplet ejection image data of the inkjet print head to be inspected within a preset number of times using a correction tool so that brightness, size, angle, and position thereof match those of the reference ink droplet image data as closely as possible, and calculate a registration accuracy between the reference ink droplet image data and the ink droplet ejection image data of the inkjet print head to be inspected.

7. The system of claim 6, wherein the registration accuracy is quantified by a registration tool, and wherein the registration tool uses any one of a feature-based technique, an intensity-based technique, and a non-rigid registration technique.

8. A method for monitoring normal ejection of inkjet ink droplets using a system for monitoring normal ejection of inkjet ink droplets using image registration accuracy, the method comprising:
performing, by a first control unit (200) of a reference system for acquiring reference image data, a calibration operation of a reference image data acquisition unit (100);
collecting, by the first control unit, ink droplet image data of an inkjet print head (H) that is normally ejecting ink, the ink droplet image data being captured by the reference image data acquisition unit, and storing the collected ink droplet image data as reference ink droplet image data;
performing, by a second control unit of a system to be inspected, a calibration operation of an inspection image data acquisition unit;
collecting, by the second control unit, comparative ink droplet image data of an inkjet print head to be inspected, the comparative ink droplet image data being captured by the inspection image data acquisition unit, and storing the collected ink droplet image data as comparative ink droplet image data;
quantifying, by the second control unit, an overall registration state between the reference ink droplet image data and the comparative ink droplet image data of the inkjet print head to be inspected, and determining whether the quantified registration value is equal to or greater than a preset value;
in the determining whether the registration value is equal to or greater than the preset value, when the registration value is less than the preset value, correcting, by the second control unit, brightness, size, angle, and vertical and horizontal positions of comparative ink droplet ejection image data of the inkjet print head to be inspected using a correction tool, thereby increasing registration accuracy between the comparative ink droplet ejection image data and the reference ink droplet image data;
in the determining whether the registration value is equal to or greater than the preset value, when the registration value is equal to or greater than the preset value, performing, by the second control unit, a local comparison of image data within a preset ROI (Region of Interest) for each nozzle in the reference ink droplet image data and the comparative ink droplet ejection image data;
determining, by the second control unit, a corresponding nozzle to be a normal inkjet print head nozzle when the registration accuracy is equal to or greater than a preset registration threshold, and determining the corresponding nozzle to be an abnormal inkjet print head nozzle when the registration accuracy is less than the preset registration threshold; and
displaying, through a display unit (300), the result determined in the determining step and the registration accuracy.
